(19) United States
(12) Patent Application Publication
(10) Pub. No.: US 2026/0053061 A1
(43) Pub. Date: Feb. 19, 2026

(54) PACKAGE STRUCTURE

(71) Applicant: Advanced Semiconductor Engineering, Inc., Kaohsiung (TW)

(72) Inventors: Hung-Yi LIN, Kaohsiung (TW); Cheng-Ting CHEN, Kaohsiung (TW); Hsu-Chiang SHIH, Kaohsiung (TW)

(73) Assignee: Advanced Semiconductor Engineering, Inc., Kaohsiung (TW)

(21) Appl. No.: 18/807,899

(22) Filed: Aug. 16, 2024

(51) Int. Cl. H01L 25/16; H01L 23/00; H01L 23/31; H01L 23/48; H01L 23/498; H01L 23/538; H10B 12/00; H10B 80/00

(52) U.S. Cl. CPC H01L 25/162; H01L 23/481; H01L 24/24; H10B 80/00; H01L 23/3135; H01L 23/49811; H01L 23/5383; H01L 24/16; H01L 24/17; H01L 24/32; H01L 24/73; H01L 2224/16146; H01L 2224/16227; H01L 2224/16507; H01L 2224/17181; H01L 2224/24146; H01L 2224/32225; H01L 2224/73204; H01L 2224/73259; H01L 2224/73267; H10B 12/00

(57) ABSTRACT

A package structure is provided. The package structure includes a first electronic component and a second electronic component, and a data access structure. The data access structure is disposed partially in a gap between the first electronic component and the second electronic component. The data access structure includes a logic portion and a storage portion. One of the logic portion and the storage portion is in the gap, and the other one of the logic portion and the storage portion is outside of the gap.

### BACKGROUND

### 1. Technical Field The present disclosure relates generally to a package structure.

### 2. Description of the Related Art

Currently, a high bandwidth memory (HBM) device is usually disposed between adjacent CPUs and arranged with the CPUs side-by-side, and the communication between the CPUs and the HBM device are achieved through bridge dies. A HBM device may include a plurality of memory dies (dynamic random-access memories; DRAMs) stacked with a logic die. The logic die is configured to receive a command signal from outside of the HBM and generate a control signal to control the memory dies, e.g., to read data from or write data to a selected memory cell of the memory dies. However, the logic die in the HBM and disposed between the CPUs usually has a relatively large size and thus may undesirably increase the transmission path between the CPUs.

### SUMMARY

In one or more arrangements, a package structure includes a first electronic component, a second electronic component, and a data access structure. The data access structure is disposed partially in a gap between the first electronic component and the second electronic component. The data access structure includes a logic portion and a storage portion. One of the logic portion and the storage portion is in the gap, and the other one of the logic portion and the storage portion is outside of the gap.

In one or more arrangements, a package structure includes a first electronic component, a second electronic component, a memory stack, and a bridging component. The memory stack includes a plurality of memory dies stacked over each other. The bridging component includes a first portion configured to provide electrical communication between the first electronic component and the second electronic component, and a second portion configured to control access to the memory stack. The second portion of the bridging component and the memory stack collectively construct a memory structure.

In one or more arrangements, a package structure includes a first electronic component, a second electronic component, and a third electronic component. The first electronic component and the second electronic component are separated from each other by a gap. The third electronic component includes a first portion and a second portion. The first portion is disposed in the gap, and the second portion extends outwards from the gap. The size of the second portion is greater than the size of the first portion.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 1A is a cross-section of a portion of a package structure in accordance with some arrangements of the present disclosure.

FIG. 1B is a cross-section of a portion of a package structure in accordance with some arrangements of the present disclosure.

FIG. 1C is a cross-section of a portion of a package structure in accordance with some arrangements of the present disclosure.

FIG. 2A is a top view of a package structure in accordance with some arrangements of the present disclosure.

FIG. 2B is a top view of a package structure in accordance with some arrangements of the present disclosure.

FIG. 2C is a top view of a package structure in accordance with some arrangements of the present disclosure.

FIG. 2D is a top view of a package structure in accordance with some arrangements of the present disclosure.

FIG. 2E is a top view of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 3C is a cross-section of a package structure in accordance with some arrangements of the present disclosure.

FIG. 3D is a cross-section of a package structure in accordance with some arrangements of the present disclosure.

FIG. 4A to FIG. 4H illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

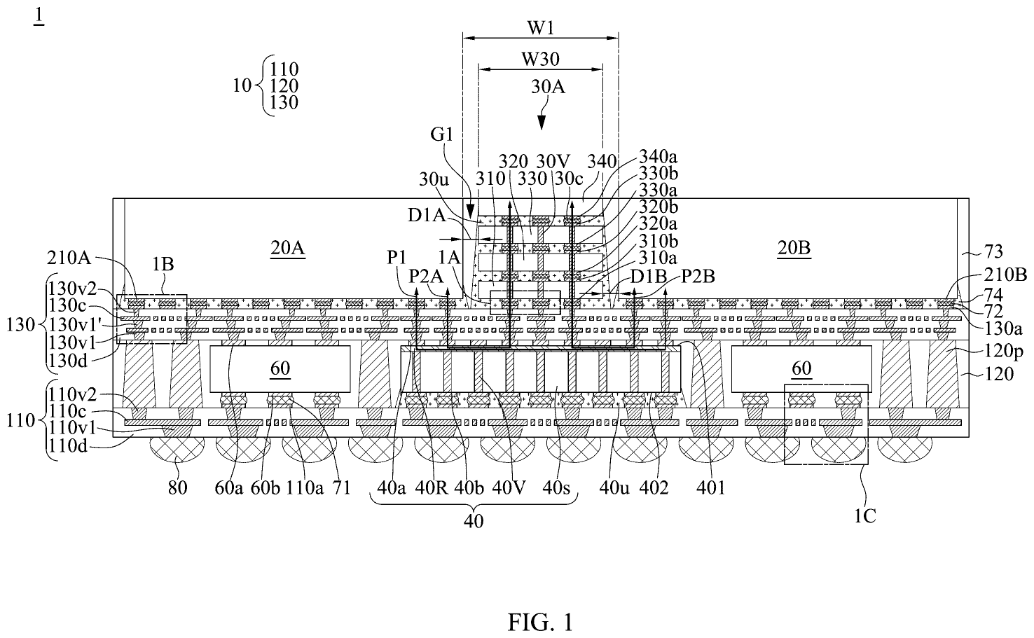

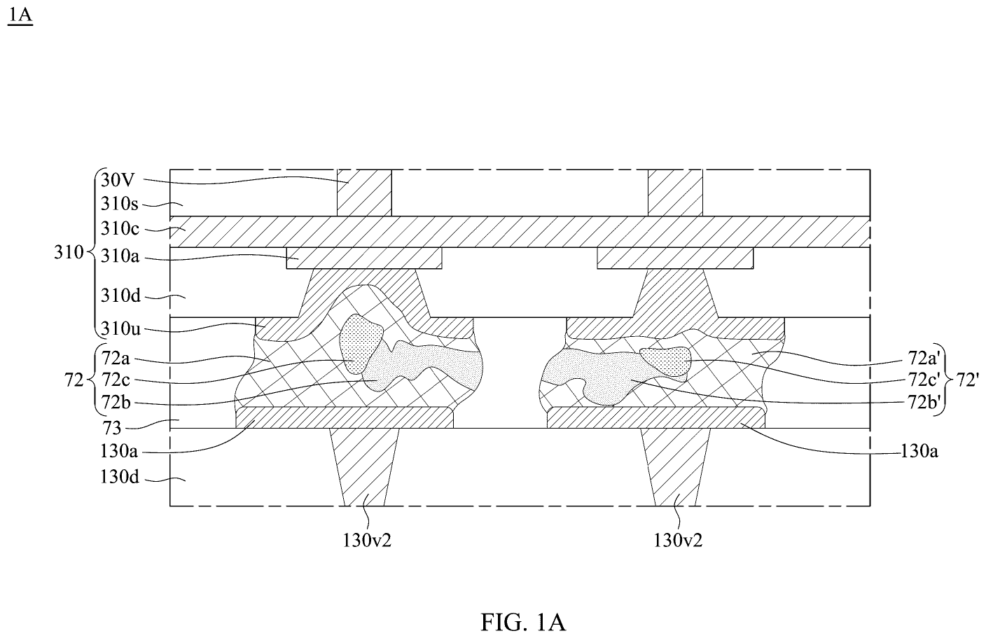

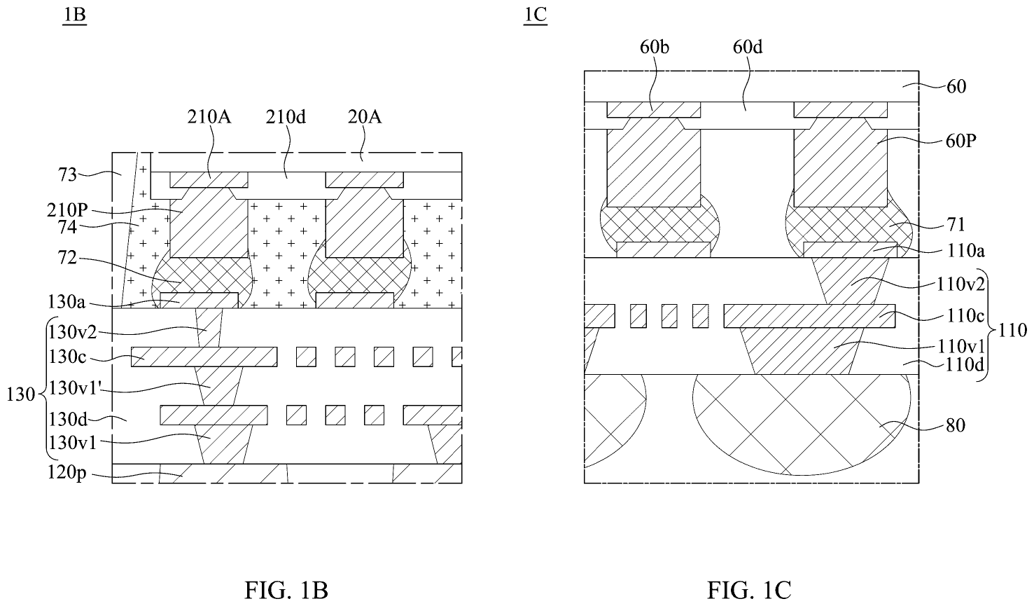

FIG. 1 is a cross-section of a package structure 1 in accordance with some arrangements of the present disclosure. The package structure 1 may include a substrate structure 10, electronic components 20A, 20B and 60, a memory stack 30A (also referred to as “a storage portion of a data access structure”), an interconnector 40 (which may include a bridge portion configured for electrical connection and a logic portion of the data access structure configured for controlling the memory stack), connection elements 71 and 72, protective elements 30u, 73, and 74, and electrical contacts 80.

The substrate structure 10 may support the electronic components 20A and 20B and the memory stack 30A. In some arrangements, the substrate structure 10 includes redistribution layers (RDLs) 110 and 130 (also referred to as “fan-out structures”), an encapsulant 120 between the RDLs 110 and 130, and conductive pillars 120p in the encapsulant 120. In some arrangements, the conductive pillars 120p are electrically connected to the RDLs 110 and 130.

In some arrangements, the RDL 110 includes a dielectric layer 110d, at least one conductive layer 110c, and conductive vias 110v1 and 110v2. A pitch of the conductive vias 110v2 may be less than a pitch of the conductive vias 110v1. A width of the conductive vias 110v2 may be less than a width of the conductive vias 110v1. The conductive layer 110c and the conductive vias 110v1 and 110v2 may include a conductive material such as a metal or metal alloy. Examples include gold (Au), silver (Ag), aluminum (Al), copper (Cu), or an alloy thereof.

In some arrangements, the encapsulant 120 connects the RDL 110 to the RDL 130. In some arrangements, the conductive pillars 120p are encapsulated by the encapsulant 120. The conductive pillars 120p may electrically connect the RDL 110 to the RDL 130. The encapsulant 120 may include an epoxy resin having fillers, a molding compound (e.g., an epoxy molding compound or other molding compound), polyimide (PI), a phenolic compound or material, a material with a silicone dispersed therein, or a combination thereof. The conductive pillars 120p may include a conductive material such as a metal or metal alloy. Examples include Au, Ag, Al, Cu, or an alloy thereof.

In some arrangements, the RDL 130 includes a dielectric layer 130d, at least one conductive layer 130c, and conductive vias 130v1, 130v1′, and 130v2. A pitch of the conductive vias 130v2 may be substantially equal to or less than a pitch of the conductive vias 130v1 and 130v1′. A width of the conductive vias 130v2 may be substantially equal to or less than a width of the conductive vias 130v1 and 130v1′. A pitch of the conductive vias 110v1 may be substantially equal to or less than a pitch of the conductive vias 130v2. A width of the conductive vias 110v1 may be substantially equal to or less than a width of the conductive vias 130v2. The conductive layer 130c and the conductive vias 130v1, 130v1′, and 130v2 may include a conductive material such as a metal or metal alloy. Examples include Au, Ag, Al, Cu, or an alloy thereof.

The electronic components 20A and 20B may be disposed over the substrate structure 10. In some arrangements, the electronic components 20A and 20B are spaced apart from each other by a gap G1 having a width W1. In some arrangements, the electronic components 20A and 20B are electrically connected to the RDL 130 (e.g., the conductive layer 130c and the conductive vias 130v1 and 130v2). In some arrangements, conductive pads 210A of the electronic components 20A and conductive pads 210B of the electronic components 20B are electrically connected to conductive pads 130a of the RDL 130 through the connection elements 72. In some arrangements, the connection elements 72 are encapsulated by the protective element 74. The electronic components 20A and 20B may include processing components (or processing elements). In some arrangements, the electronic components 20A and 20B may independently include an ASIC, a SOC (system on a chip), an FPGA, a GPU, or the like, or a combination thereof. In some arrangements, the electronic components 20A and 20B may independently include a processing core or a processing chiplet. The conductive pads 210A, 210B, and 130a may include a conductive material such as a metal or metal alloy. Examples include Au, Ag, Al, Cu, or an alloy thereof. The connection elements 72 may include conductive bumps, which may be or may include Ag, Al, Cu, another metal, a solder alloy, or a combination thereof. The protective element 77 may include an underfill, which may include an epoxy resin having fillers, a molding compound (e.g., an epoxy molding compound or other molding compound), polyimide (PI), a phenolic compound or material, a material with a silicone dispersed therein, or a combination thereof.

The package structure 1 may include a data access structure including a storage portion configured to store data and a logic portion configured to access the storage portion. The data access structure may be or include a HBM device, the storage portion may be or include memory elements, and the logic portion may be or include a logic die. The logic portion or the logic die is configured to receive a command signal from outside of the data access structure (or the HBM device) and generate a control signal to access the storage portion (or the memory elements). In some arrangements, one of the electronic components 20A and 20B is configured to access the storage portion through the logic portion. In some arrangements, one of the logic portion and the storage portion has a first size, the other one of the logic portion and the storage portion has a second size greater than the first size, the one having the second size is outside of the gap G1, and the one having the first size is in the gap G1. In some arrangements, the storage portion may be the memory stack 30A, and the logic portion may be located outside of the gap G1 between the electronic components 20A and 20B. The logic portion of the logic die disposed outside of the gap G1 can prevent the width W1 of the gap G1 from being undesirably enlarged by the relatively wide logic portion (or the logic die) stacked with the storage portion (or the memory elements), and thus the transmission path between the electronic components 20A and 20B can be prevented from being undesirably enlarged. In some arrangements, the memory stack 30A is disposed adjacent to the electronic components 20A and 20B. In some arrangements, the memory stack 30A is disposed in the gap G1 between the electronic components 20A and 20B. The memory stack 30A may be disposed over the substrate structure 10. In some arrangements, the memory stack 30A is electrically connected to the RDL 130 (e.g., the conductive layer 130c and the conductive vias 130v1, 130v1′, and 130v2). In some arrangements, conductive pads of the memory stack 30A are electrically connected to conductive pads 130a of the RDL 130 through the connection elements 72. In some arrangements, the memory stack 30A has a width W30, the memory stack 30A is spaced apart from the electronic component 20A by a distance D1A, and the memory stack 30A is spaced apart from the electronic component 20B by a distance D1B. In some arrangements, the memory stack 30A does not include a logic die stacked with the memory stack 30A in the gap G1.

In some arrangements, the memory stack 30A includes a plurality of memory dies (e.g., memory dies 310, 320, 330, and 340) stacked over each other and connection elements 30c electrically connecting the memory dies. The memory dies may include DRAMs. One or more of the memory dies may include conductive vias 30V (e.g., TSVs) electrically connected to the connection elements 30c. In some arrangements, the protective element 30u at least partially encapsulates the memory stack 30A and is spaced apart from the circuit layer 40R of the interconnector 40. The conductive vias 30V may penetrate opposite surfaces of the memory die. In some arrangements, conductive pads 340a of the memory die 340 electrically connect to conductive pads 330b of the memory die 330 through the connection elements 30c. In some arrangements, conductive pads 330a of the memory die 330 electrically connect to conductive pads 320b of the memory die 320 through the connection elements 30c. In some arrangements, conductive pads 320a of the memory die 320 electrically connect to conductive pads 310b of the memory die 310 through the connection elements 30c. In some arrangements, conductive pads 310a of the memory die 310 electrically connect to the conductive pads 130a of the RDL 130 through the connection elements 72.

The interconnector 40 may be disposed below the memory stack 30A. The interconnector 40 may be referred to as a bridging component and also configured to function as a logic die of a HBM device. In some arrangements, the interconnector 40 is configured to provide an electrical communication between the electronic components 20A and 20B. In some arrangements, at least one of the electronic components 20A and 20B is configured to access the memory stack 30A through the portion of the interconnector 40 that functions as a logic die in a HBM device. In some arrangements, the interconnector 40 is embedded in the substrate structure 10. In some arrangements, the interconnector 40 is disposed between the RDL 110 and the RDL 130 and encapsulated by the encapsulant 120. In some arrangements, the interconnector 40 is electrically connected to the RDL 110 and the RDL 130.

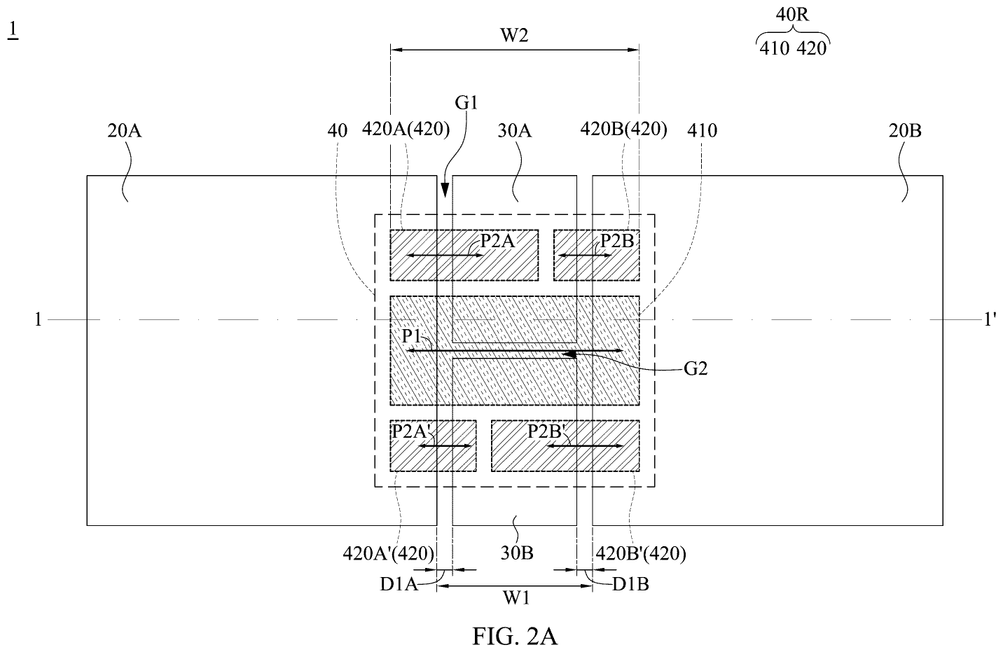

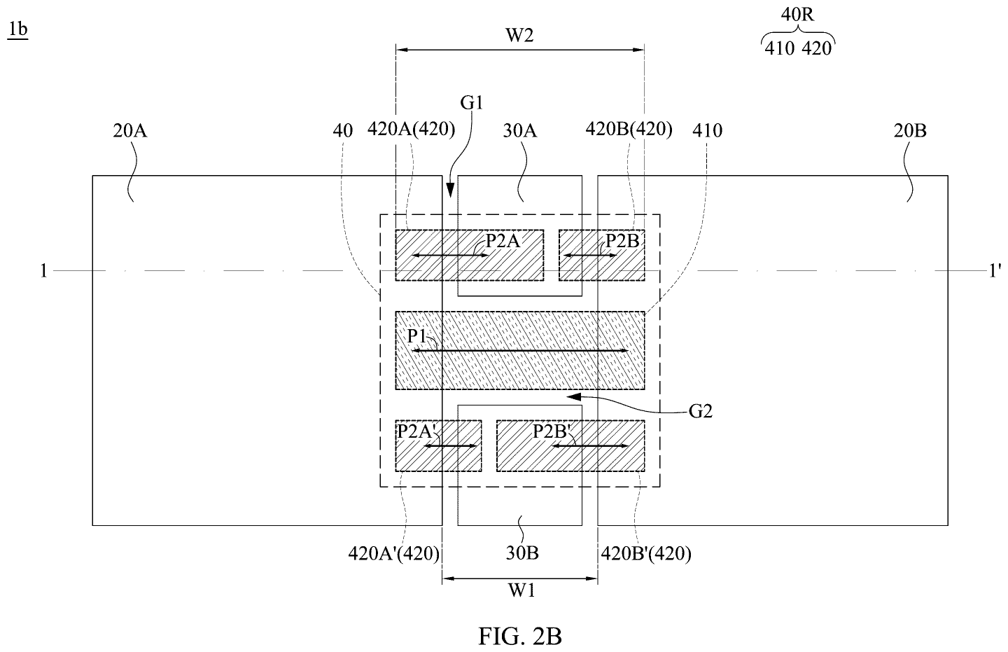

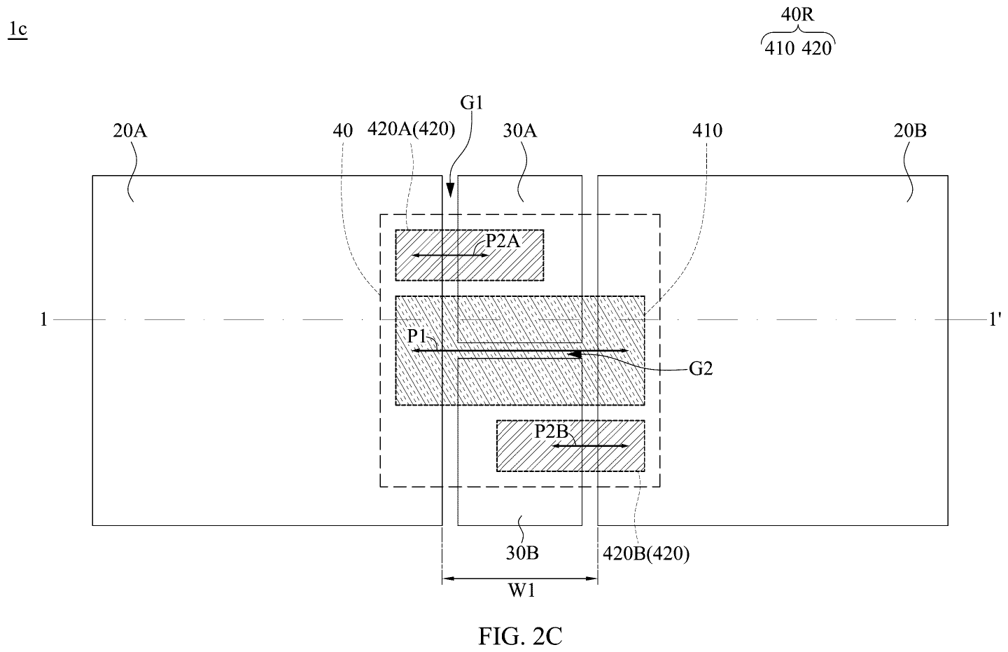

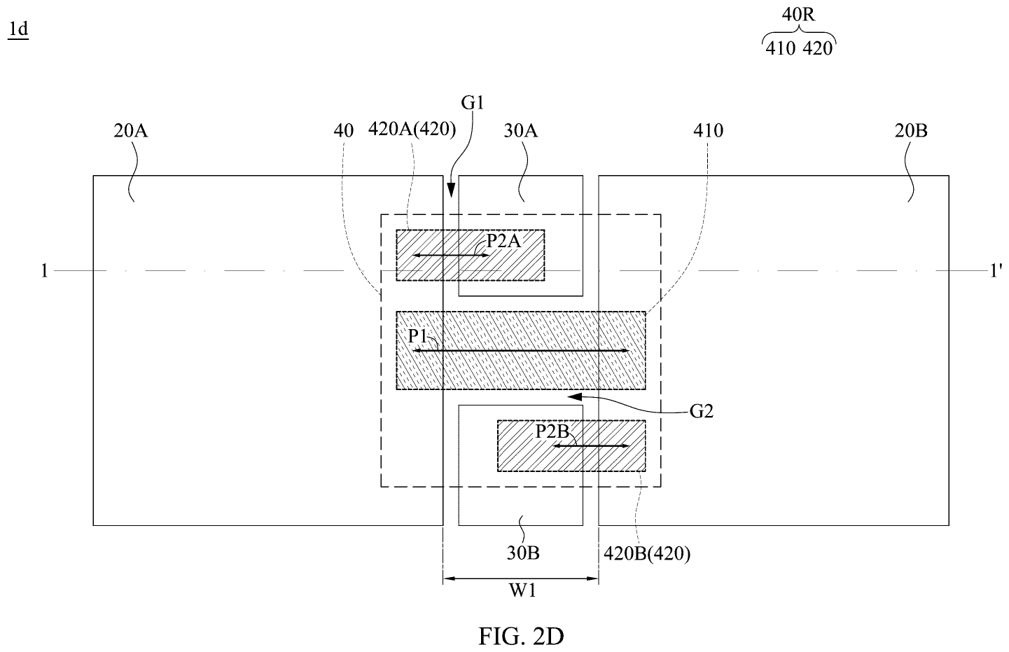

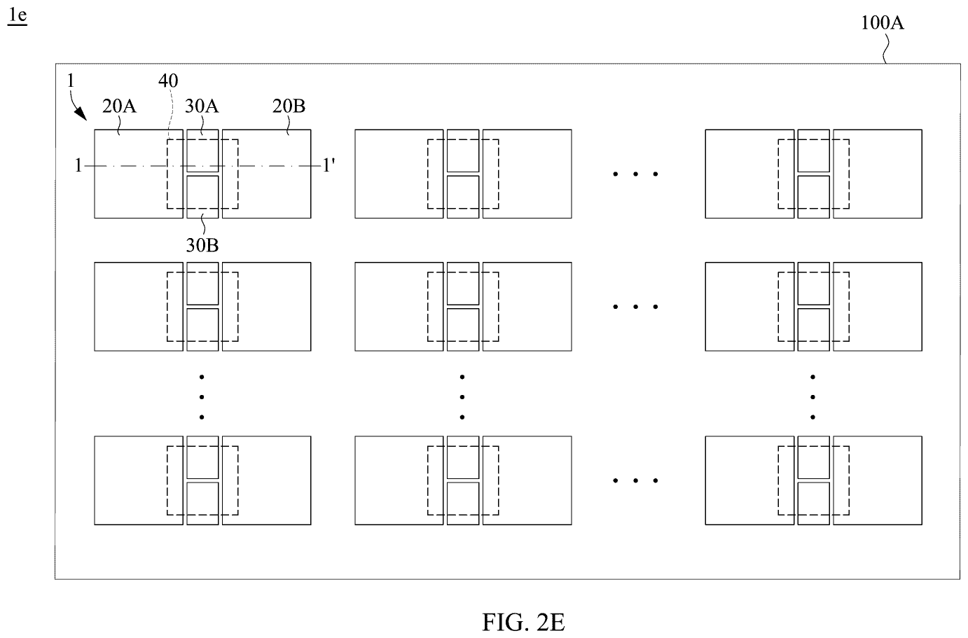

In some arrangements, the interconnector 40 includes a base layer 40s, a circuit layer 40R over the base layer 40s, conductive pads 40a on a surface 401 (also referred to as “a top surface”), conductive pads 40b on a surface 402 (also referred to as “a bottom surface”) opposite to the surface 401, and conductive vias 40V extending between the surfaces 401 and 402 to electrically connect the conductive pads 40a and 40b. In some arrangements, the base layer 40s includes a semiconductor substrate layer, e.g., a Si layer. In some arrangements, the circuit layer 40R includes a bridge portion configured to provide electrical connection and a logic portion configured to generate control signals to perform a write operation and/or a read operation to the memory stack 30A (or the storage portion of a data access structure). In some arrangements, the circuit layer 40R includes a bridging circuit or the bridge portion (e.g., a circuit 410 shown in FIGS. 2A to 2D) configured to provide the electrical communication between the electronic components 20A and 20B. In some arrangements, the circuit layer 40R includes a control logic circuit or the logic portion (e.g., a circuit 420 shown in FIGS. 2A to 2D) configured to control access to the memory stack 30A. In some arrangements, the control logic circuit (or the logic portion) is configured to generate control signals to perform a write operation and/or a read operation.

In some arrangements, a wafer node of the circuit layer 40R (or the control logic circuit) is less than or smaller than a wafer node of the memory stack 30A (or the memory dies). A wafer node of the circuit layer 40R (or the control logic circuit) may lead a wafer node of the memory stack 30A (or the memory dies) by one or more generations. For example, the circuit layer 40R (or the control logic circuit) may be a 7 nm or less node wafer, and the memory dies may be a 14 nm or more node wafer, such as a 16 nm or more node wafer, a 20 nm or more node wafer, or greater.

In some arrangements, the interconnector 40 is configured to provide the electrical communication between the electronic components 20A and 20B along a path P1. In some arrangements, the path P1 includes vertical parts passing the RDL 130 and connecting the electronic components 20A and 20B to the interconnector 40. In some arrangements, the path P1 includes a horizontal part passing the circuit layer 40R without passing a portion of the RDL 130 under the memory stack 30A. In some arrangements, the path P1 vertically overlaps the memory stack 30A from a cross-sectional view perspective. In some arrangements, the electronic component 20A is configured to access the memory stack 30A along a path P2A. In some arrangements, the electronic component 20B is configured to access the memory stack 30A along a path P2B. In some arrangements, the paths P2A and P2B include vertical parts that directly connect the circuit layer 40R to the memory stack 30A without passing a logic die. In some arrangements, the path P2A and the path P2B are at least partially substantially parallel to the path P1.

In some arrangements, the control logic circuit (or the logic portion) of the interconnector 40 and the memory stack 30A collectively construct a memory structure (or the data access structure). The memory structure (or the data access structure) may be or include a high bandwidth memory (HBM) device. The memory structure (or the data access structure) may be referred to as an additional electronic component distinct from the electronic components 20A and 20B. The memory stack 30A (or the storage portion) and the control logic circuit (or the logic portion) of the interconnector 40 may be referred to as two portions that are dissembled from each other and electrically connected to each other by a conductive structure (e.g., the RDL 130). In some arrangements, the memory stack 30A (or a first portion of the additional electronic component) is configured to be unable to operably communicate with the electronic component 20A and/or the electronic component 20B without operating in conjunction with the control logic circuit of the interconnector 40 (or a second portion of the additional electronic component). In some arrangements, the control logic circuit of the interconnector 40 (or the second portion of the additional electronic component) is configured to operate in conjunction with the memory stack 30A (or the first portion of the additional electronic component) to operably communicate with the electronic component 20A and/or the electronic component 20B.

In some arrangements, the path P2A passes a portion of the RDL 130 under the electronic component 20A, a portion of the circuit layer 40R where control signals are generated by the control logic circuit (or the logic portion) and transmitted by the bridging circuit (or the bridge portion), and a portion of the RDL 130 under the memory stack 30A. In some arrangements, the path P2B passes a portion of the RDL 130 under the electronic component 20B, a portion of the circuit layer 40R where control signals are generated by the control logic circuit (or the logic portion) and transmitted by the bridging circuit (or the bridge portion), and a portion of the RDL 130 under the memory stack 30A.

In some arrangements, the RDL 130 is over the interconnector 40 and electrically connected to the surface 401 (or the top surface) of the interconnector 40. In some arrangements, the interconnector 40 is electrically connected to the RDL 130 through the conductive pads 40a. In some arrangements, the memory stack 30A and the circuit layer 40R are at opposite sides of the RDL 130. In some arrangements, the RDL 130 is between the memory stack 30A and the interconnector 40, and the RDL 130 electrically connects the surface 401 (of the top surface) of the interconnector 40 to the memory stack 30A. In some arrangements, the RDL 130 is between the electronic components 20A and 20B and the interconnector 40, and at least one of the electronic components 20A and 20B is configured to transmit an electrical signal to the circuit layer 40R of the interconnector 40 by an electrical path (e.g., the path P1, the path P2A, and/or the path P2B) passing the RDL 130 once. In some arrangements, the control logic circuit (e.g., the circuit 420 shown in FIGS. 2A to 2D) of the circuit layer 40R is configured to access data in the memory stack 30A by a path (e.g., the path P2A and/or the path P2B) passing the RDL 130. In some arrangements, the encapsulant 120 encapsulates the control logic circuit (e.g., the circuit 420 shown in FIGS. 2A to 2D) of the circuit layer 40R and is spaced apart from the memory stack 30A. The control logic circuit (or the logic portion) may include a transceiver including a physical-layer circuit or a physical-layer interface portion (normally abbreviated as “PHY”), which connects a physical medium through which data is transmitted between the electronic components 20A and 20B and the interconnector 40 through the conductive pads 40a, the RDL 130, and the conductive pads 210A and 210B.

In some arrangements, the RDL 110 is below the interconnector 40 and electrically connected to the surface 402 (or the bottom surface) of the interconnector 40. In some arrangements, the conductive pads 40b of the interconnector 40 are electrically connected to conductive pads 110a of the RDL 110 through connection elements 71. The conductive pads 110a may be or include under-bump metallization (UBM) layers. The connection elements 71 may include conductive bumps, which may be or may include Ag, Al, Cu, another metal, a solder alloy, or a combination thereof. In some arrangements, the interconnector 40 may further include a protective element 40u encapsulating the conductive pads 40b and 110a and the connection elements 71. The protective element 40u may be or include an underfill, including an epoxy resin having fillers, a molding compound (e.g., an epoxy molding compound or other molding compound), polyimide (PI), a phenolic compound or material, a material with a silicone dispersed therein, or a combination thereof.

The electronic components 60 may be embedded in the substrate structure 10. In some arrangements, the electronic components 60 are encapsulated by the encapsulant 120. The electronic component 60 may include conductive pads 60a and 60b on opposite surfaces of the electronic component 60. In some arrangements, the electronic components 60 are electrically connected to the RDL 110 through the conductive pads 60a and to the RDL 130 through the conductive pads 60b. The conductive pads 60a and 60b may include a conductive material such as a metal or metal alloy. Examples include Au, Ag, Al, Cu, or an alloy thereof. The electronic component 60 may be or include a passive component, e.g., a capacitor, an inductor, or other suitable passive component. In some arrangements, the electronic component 60 is or includes a deep-trench-capacitor (DTC).

The protective element 73 may encapsulate the electronic components 20A and 20B, the memory stack 30A, the connection elements 72, and the protective elements 30u and 74. In some arrangements, the protective element 73 encapsulates the conductive pads 310a, 310b, 320a, 320b, 330a, 330b, and 340a and the connection elements 30c. The protective element 73 may include an encapsulant, an epoxy resin having fillers, a molding compound (e.g., an epoxy molding compound or other molding compound), polyimide (PI), a phenolic compound or material, a material with a silicone dispersed therein, or a combination thereof.

The electrical contacts 80 may be disposed under the RDL 110. In some arrangements, the electrical contacts 80 are electrically connected to the RDL 110. The electrical contacts 80 may include solder balls. The electrical contacts 80 may be or include controlled collapse chip connection (C4) bumps, a ball grid array (BGA), or a land grid array (LGA).

According to some arrangements of the present disclosure, the control logic circuit of the circuit layer 40R is integrated into the interconnector 40 instead of formed of a single logic die and stacked with the memory dies 310, 320, 330, and 340 in the gap G1 between the electronic components 20A and 20B. As such, the memory stack 30A does not include a logic die having a width greater than that of the memory dies and stacked with the memory dies and. Therefore, the distances D1A and D1B between the memory stack 30A and the electronic components 20A and 20B, respectively, can be minimized, thus the width W1 of the gap G1 can be prevented from being undesirably enlarged by the relatively wide logic die stacked with the memory dies. As a result, the distance (e.g., the width W1 of the gap G1) between the electronic components 20A and 20B can be reduced, thus the transmission path between the electronic components 20A and 20B can be reduced, and the transmission path between the memory stack 30A and the electronic components 20A and 20B can be reduced as well. Therefore, the transmission loss can be reduced, the power efficiency can be increased, the signal decay can be reduced, and the latency can be reduced as well.

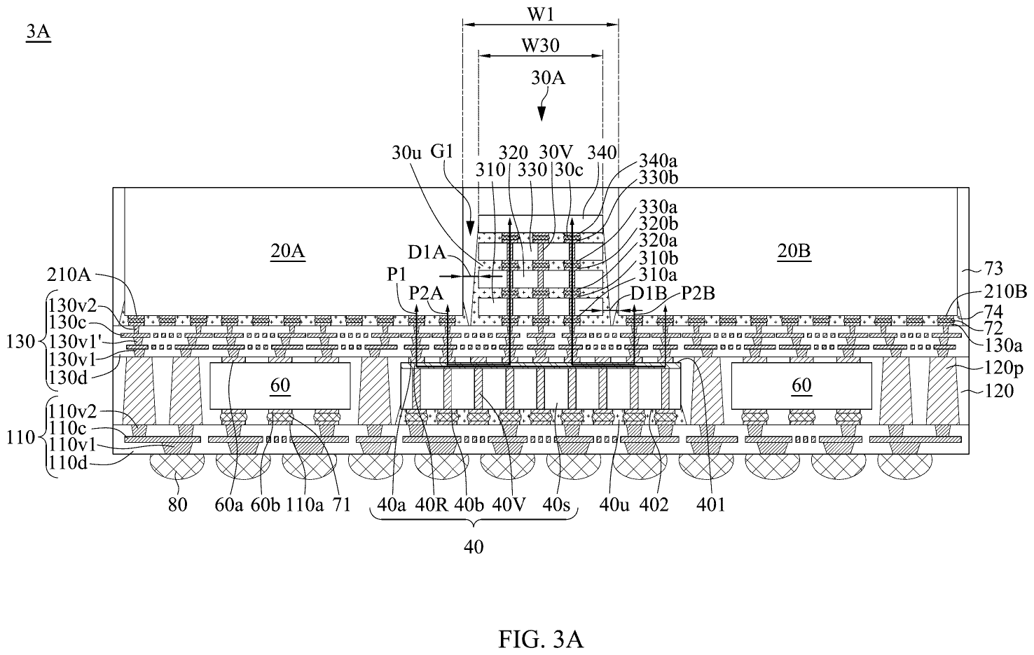

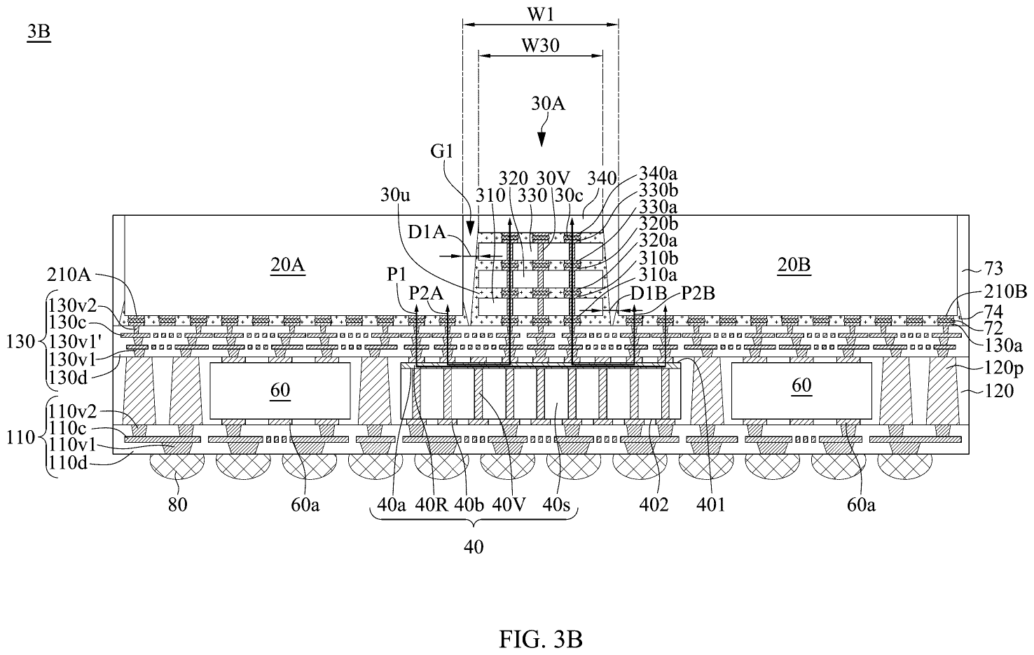

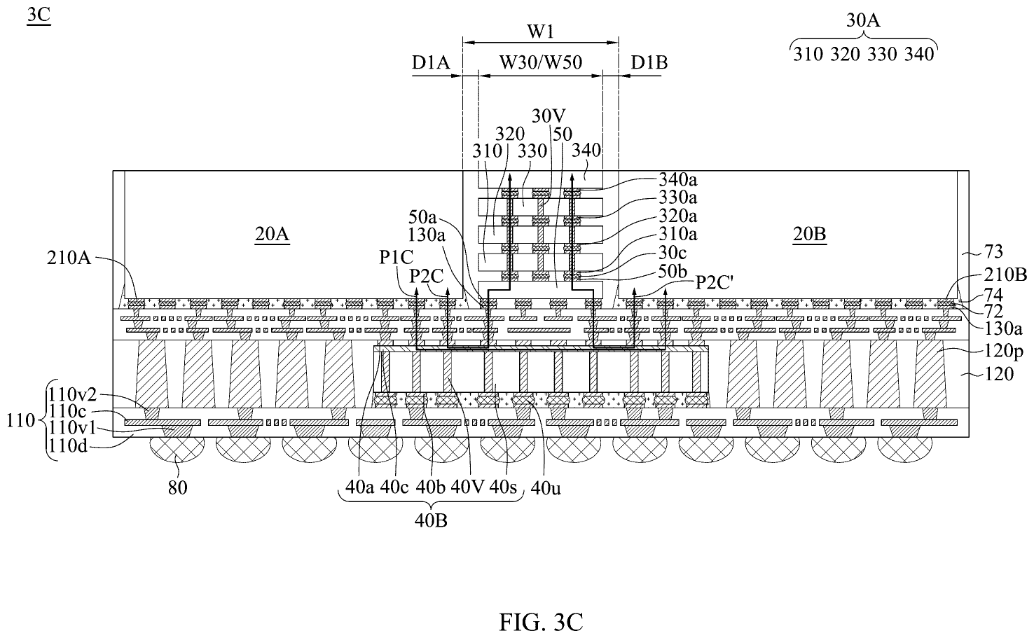

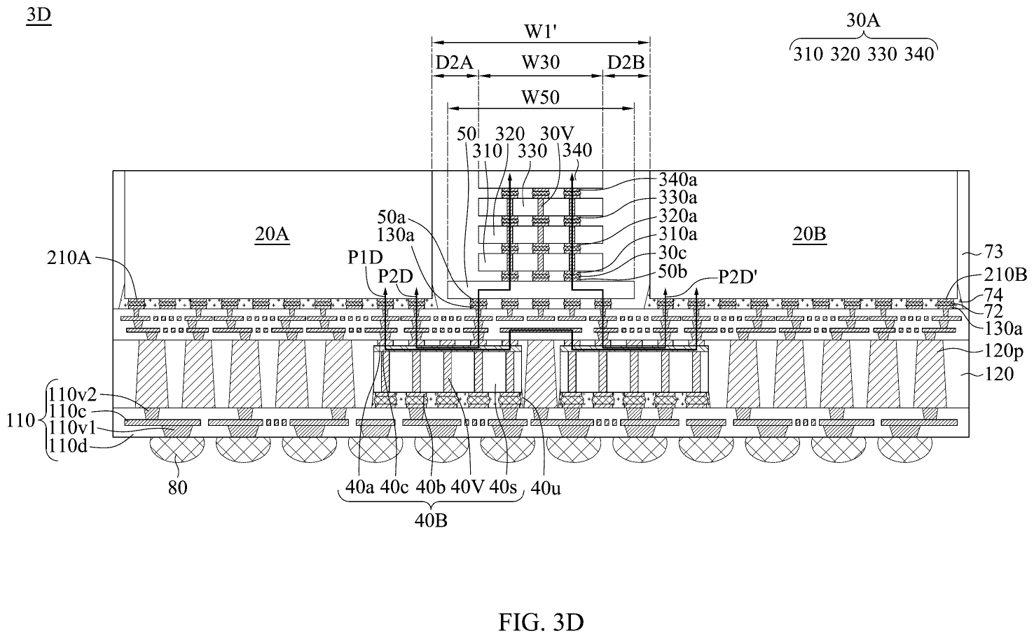

Moreover, a HBM device including a memory stack (e.g., the memory stack 30A) and a logic die (e.g., the logic die 50 illustrated in FIG. 3D) integrated together may have a relatively large thickness, for example, the thickness of the HBM device may be greater than the thickness of the interconnector 40. Therefore, when a whole HBM device including the memory stack and the logic die is disposed or embedded in the encapsulant 120 in order to reduce the size of the gap G1 between the electronic components 20A and 20B, the thickness of the entire package structure may be undesirably increased. In contrast, according to some arrangements of the present disclosure, only a portion (e.g., the control logic circuit of the circuit layer 40R) of a memory structure (e.g., a HBM device) is disposed or embedded in the encapsulant 120 with another portion (the memory stack 30A) of the memory structure remains disposed in the gap G1. Therefore, the thickness of the entire package structure 1 is not increased, and the distance (e.g., the gap G1) between the electronic components 20A and 20B can be shortened.

In addition, according to some arrangements of the present disclosure, the bridging circuit (or the bridge portion) for electrically communicating the electronic components 20A and 20B are integrated into the circuit layer 40R of the interconnector 40 instead of disposing two bridge components to electrically communicate to the two electronic components 20A and 20B respectively. Therefore, the process is simplified by manufacturing one bridging structure (e.g., the interconnector 40) rather than manufacturing two bridging components in the package structure. Moreover, according to some arrangements of the present disclosure, the path P1 for electrically communicating the electronic components 20A and 20B may pass the RDL 130 only twice and extends along the circuit layer 40R of the interconnector 40 instead of passing two bridge components each connected to each of the electronic components 20A and 20B. Therefore, the path P1 may pass less heterogeneous interfaces (e.g., interfaces between the RDL 130 and the interconnector 40), and the path P1 can be relatively short, which is further advantageous to lowering the power consumption, the signal decay, and latency.

Moreover, according to some arrangements of the present disclosure, the control logic circuit (or the logic portion) for accessing memory stack 30A is further integrated into the circuit layer 40R of the interconnector 40 instead of stacking a logic die with the memory stack 30A to electrically communicate the electronic components 20A and 20B with the memory stack 30A. Therefore, the process is further simplified by manufacturing one integrated structure (e.g., the interconnector 40) rather than manufacturing one logic die and two bridging components. In addition, according to some arrangements of the present disclosure, the path (e.g., the paths P2A and P2B) for electrically communicating the electronic components 20A and 20B with the memory stack 30A passes a portion of the circuit layer 40R for control signal generation and signal transmission without further passing a logic die. Therefore, the paths P2A and P2B can be relatively short, which is further advantageous to increasing the computing speed and lowering the power consumption, the signal decay, and latency.

Furthermore according to some arrangements of the present disclosure, the interconnector 40 integrates the bridging function (e.g., the bridging circuit) and the computing function (e.g., the control logic circuit) into a single unit to form the package structure 1 (also referred to as “a combo die”). As such, the distance between the wirings of the bridging circuit (or the bridge portion) and the control logic circuit (or the logic portion) is decreased, such that the transmission distance between the bridging circuit (or the bridge portion) and the control logic circuit (or the logic portion) is decreased. Therefore, the computing speed within the interconnector 40 of the package structure 1 (or the combo die) is increased, and thus the performance of the package structure 1 is increased. In addition, multiple package structures 1 including the interconnectors 40 each with multiple functions can serve as combo dies integrated into various devices or packages, such that the scalability and applications of the package structure 1 can be increased.

Moreover, according to some arrangements of the present disclosure, the interconnector 40 includes the conductive vias 40V that connect the conductive pads 40a and 40b on opposite surfaces 401 and 402. Therefore, the transmission speed can be further increased by vertical transmission, such that the band width can be increased, the latency can be lowered, and the power consumption and the heat generated can be reduced.

In addition, according to some arrangements of the present disclosure, a wafer node of the control logic circuit (or the logic die) is less than or smaller than a wafer node of the memory stack 30A, and the memory stack 30A is manufactured separately from the control logic circuit instead of manufacturing the memory stack 30A and a logic die into one memory module. Therefore, the precision required for manufacturing the memory stack 30A is less than that for manufacturing the control logic circuit (or the logic die), and processes requiring different levels of processing precision are performed separately, such that the overall process can be simplified, and the costs can be reduced. In addition, the control logic circuit is manufactured separately from the memory stack 30A, whether the interconnector 40 with the control logic circuit and the memory stack 30A are known good dies (KGDs) and/or known bad dies (KBDs) can be identified before proceeding the manufacturing process, only the KGDs are used, and the KBDs can be reworked or replaced. Therefore, the yield can be increased.

FIG. 1A is a cross-section of a portion of a package structure in accordance with some arrangements of the present disclosure. In some arrangements, FIG. 1A is a cross-section of a portion 1A of the package structure 1 illustrated in FIG. 1.

In some arrangements, the memory die 310 includes a substrate layer 310s, a device layer 310c, conductive vias 30V, conductive pads 310a, and a dielectric layer 310d. In some arrangements, the substrate layer 310s includes a semiconductor substrate layer, e.g., a Si layer. The conductive vias 30V may penetrate the substrate layer 310s and connect to the device layer 310c. The conductive pads 310a may be electrically connected to the device layer 310c. The device layer 310c may include storage elements, such as capacitors or the like. The dielectric layer 310d may partially cover the device layer 310c and the conductive pads 310a. The conductive pads 310a and 310b and the conductive vias 30V may include a conductive material such as a metal or metal alloy. Examples include Au, Ag, Al, Cu, or an alloy thereof. The memory dies 320, 330, and 340 illustrated in FIG. 1 may independently include a structure similar to that of the memory die 310. The topmost memory die (e.g., the memory die 340) may be free of the conductive vias 30V.

In some arrangements, the memory die 310 further includes conductive layers 310u. The conductive layers 310u may be disposed on exposed portions of the conductive pads 310a. The conductive layers 310u may be referred to as under-bump metallization (UBM) layers. In some arrangements, conductive pads 310a are connected to the conductive pads of the RDL 130 through the conductive layers 310u and the connection elements 72 and 72′.

In some arrangements, the connection element 72 includes an alloy layer 72a, a bonding layer 72c, and an intermetallic compound (IMC) layer 72b. In some arrangements, the bonding layer 72c includes a soldering material. In some arrangements, the alloy layer 72a includes a metal element of the soldering material and a metal element of the conductive layer 310u. In some arrangements, the IMC layer 72b includes one or more metal elements of the soldering material and a metal element of the conductive layer 310u. For example, the alloy layer 72a may include Ni—Sn alloy, the bonding layer 72c may include Au—Sn alloy, and the IMC layer 72b may include Au—Sn—Ni IMC. In some arrangements, the conductive layer 310u is misaligned with the conductive pad 130a.

In some arrangements, the connection element 72′ includes an alloy layer 72a′, a bonding layer 72c′, and an IMC layer 72b′. In some arrangements, the bonding layer 72c′ includes a soldering material. In some arrangements, the alloy layer 72a′ includes a metal element of the soldering material and a metal element of the conductive layer 310u. In some arrangements, the IMC layer 72b′ includes one or more metal elements of the soldering material and a metal element of the conductive layer 310u. For example, the alloy layer 72a′ may include Ni—Sn alloy, the bonding layer 72c′ may include Au—Sn alloy, and the IMC layer 72b′ may include Au—Sn—Ni IMC. In some arrangements, the geometric structure of the connection element 72 is different from the geometric structure of the connection element 72′.

FIG. 1B is a cross-section of a portion of a package structure in accordance with some arrangements of the present disclosure. In some arrangements, FIG. 1B is a cross-section of a portion 1B of the package structure 1 illustrated in FIG. 1.

In some arrangements, the electronic component 20A includes the conductive pad 210A, a dielectric layer 210d defining an opening exposing the conductive pad 210A, and a connection element 210P. The connection element 210P may be or include a conductive pillar. The conductive pad 210A may be electrically connected to the conductive pad 130a through the connection element 72. The conductive pad 210A may be misaligned with the conductive pad 130a. In some arrangements, a thickness of the conductive pad 130a is less than a thickness of the connection element 72, and the thickness of the connection element 72 is less than a thickness of the connection element 210P.

FIG. 1C is a cross-section of a portion of a package structure in accordance with some arrangements of the present disclosure. In some arrangements, FIG. 1C is a cross-section of a portion 1C of the package structure 1 illustrated in FIG. 1.

In some arrangements, the electronic component 60 includes the conductive pad 60b, a dielectric layer 60d defining an opening exposing the conductive pad 60b, and a connection element 60P. The connection element 60P may be or include a conductive pillar. The conductive pad 60b may be electrically connected to the conductive pad 110a through the connection element 71. The conductive pad 60b may be misaligned with the conductive pad 110a. In some arrangements, a thickness of the conductive pad 110a is less than a thickness of the connection element 71, and the thickness of the connection element 71 is less than a thickness of the connection element 60P.

FIG. 2A is a top view of a package structure 1 in accordance with some arrangements of the present disclosure. In some arrangements, FIG. 2A is a top view of the package structure 1 illustrated in FIG. 1. In some arrangements, FIG. 1 shows a cross-section along a line 1-1′ in FIG. 2A.

In some arrangements, the package structure 1 includes a plurality of memory stacks (e.g., memory stacks 30A and 30B). In some arrangements, the memory stacks 30A and 30B are over the interconnector 40. The memory stack 30B may have a structure similar to that of the memory stack 30A including the memory dies 310, 320, 330, and 340. In some arrangements, the memory stacks 30A and 30B are spaced apart from each other by a gap G2.

In some arrangements, the interconnector 40 (or the circuit layer 40R) includes a circuit 410 and a circuit 420 distinct from the circuit 410. In some arrangements, the circuits 410 and 420 are partially covered by the electronic components 20A and 20B from a top view perspective. In some arrangements, the circuits 410 and 420 are partially covered by the memory stacks 30A and 30B from a top view perspective.

In some arrangements, the circuit 410 may be referred to as a bridging circuit (or the bridge portion). In some arrangements, the circuit 410 is configured to provide an electrical communication between the electronic components 20A and 20B. In some arrangements, the circuit 410 (or the bridging circuit) is configured to transmit one or more electrical signals between the electronic components 20A and 20B by a path P1. In some arrangements, the circuit 410 is at least partially between the memory stacks 30A and 30B from a top view perspective. In some arrangements, the circuit 410 is at least partially exposed by the gap G2 between the memory stacks 30A and 30B.

Referring to FIG. 1 and FIG. 2A, in some arrangements, the circuit 410 of the circuit layer 40R vertically overlaps the memory stacks 30A and 30B from a cross-sectional view perspective. In some arrangements, the RDL 130 is between the electronic components 20A and 20B and the interconnector 40, and at least one of the electronic components 20A and 20B is configured to transmit one or more electrical signals to the circuit 410 (or the bridging circuit) of the circuit layer 40R of the interconnector 40 by an electrical path (e.g., the path P1) passing the RDL 130 once.

In some arrangements, the circuit 420 may be referred to as a logic circuit or a control logic circuit (or a logic portion of the data access structure). In some arrangements, the circuit 420 is configured to control access to the memory stacks. In some arrangements, the circuit 420 is configured to control access to one or more of the memory stacks 30A and 30B. The circuit 420 may be configured to generate control signals to perform a write operation and/or a read operation. In some arrangements, the electronic component 20A is configured to access the memory stacks 30A and 30B through the circuit 420. In some arrangements, the electronic component 20B is configured to access the memory stacks 30A and 30B by sending a command signal to the circuit 420 (or the logic portion of the data access structure) which is configured to generate a control signal in response to the command signal to access the memory stacks 30A and 30B (or the storage portion of the data access structure). In some arrangements, the circuit 420 overlaps a portion of the memory stacks 30A and 30B, a portion of the electronic component 20A, and a portion of the electronic component 20B from a top view perspective. In some arrangements, the circuit 420 is at least partially between the memory stacks 30A and 30B and the electronic components 20A and 20B from a top view perspective. In some arrangements, the circuit 420 is at least partially exposed by the gap G1 between the electronic components 20A and 20B.

In some arrangements, the circuit 420 includes portions 420A and 420B (also referred to as “circuit regions”). In some arrangements, the electronic component 20A is configured to access the memory stack 30A by sending a command signal to the portion 420A which is configured to generate a control signal in response to the command to access the memory stack 30A, and the electronic component 20B is configured to access the memory stack 30A by sending a command signal to the portion 420B which is configured to generate a control signal in response to the command signal to access the memory stack 30A. In some arrangements, the portions 420A and 420B of the circuit 420 are located at a same side of the circuit 410 from a top view perspective. In some arrangements, a width W2 of the circuit 420 is greater than the width W1 of the gap G1 between the electronic components 20A and 20B. In some arrangements, the width W2 of the circuit 420 (or the control logic circuit) is greater than a distance (e.g., the width W1) between the electronic components 20A and 20B.

In some arrangements, the circuit 420 further includes portions 420A′ and 420B′ (also referred to as “circuit regions”). In some arrangements, the electronic component 20A is configured to access the memory stack 30B by sending a command signal to the portion 420A′ which is configured to generate a control signal in response to the command signal to access the memory stack 30B, and the electronic component 20B is configured to access the memory stack 30B by sending a command signal to the portion 420B′ which is configured to generate a control signal in response to the command signal to access the memory stack 30B. In some arrangements, the portions 420A′ and 420B′ of the circuit 420 are located at a same side of the circuit 410 from a top view perspective.

In some arrangements, the circuit 420 (or the control logic circuit) is configured to access data in one or more of the memory stacks 30A and 30B by a path (e.g., at least one of paths P2A, P2B, P2A′, and P2B′). In some arrangements, the portion 420A (or the circuit region) of the circuit 420 is configured to access data in the memory stack 30A by a path P2A. In some arrangements, the portion 420B (or the circuit region) of the circuit 420 is configured to access data in the memory stack 30A by a path P2B. In some arrangements, the portion 420A′ (or the circuit region) of the circuit 420 is configured to access data in the memory stack 30B by a path P2A′. In some arrangements, the portion 420B′ (or the circuit region) of the circuit 420 is configured to access data in the memory stack 30B by a path P2B′.

Referring to FIG. 1 and FIG. 2A, in some arrangements, the circuit 420 (or the control logic circuit) of the circuit layer 40R is embedded in the encapsulant 120. In some arrangements, the electronic component 20A (or the processing element) is over the substrate structure 10 and configured to access one or more of the memory stacks 30A and 30B by sending a command signal to the circuit 420 (or the control logic circuit) which is configured to generate a control signal in response to the command signal to access one or more of the memory stacks 30A and 30B. In some arrangements, the electronic component 20B (or the processing element) is over the substrate structure 10 and configured to access one or more of the memory stacks 30A and 30B by sending a command signal to the circuit 420 (or the control logic circuit) which is configured to generate a control signal in response to the command signal to access one or more of the memory stacks 30A and 30B. In some arrangements, the encapsulant 120 encapsulates the circuit 420 (or the control logic circuit) and spaced apart from the memory stacks 30A and 30B. In some arrangements, the conductive pads 40a are embedded in the encapsulant 120 and electrically connecting the circuit 420 (or the control logic circuit) to one or more of the memory stacks 30A and 30B. In some arrangements, the conductive pads 40a electrically connect the circuit 420 (or the control logic circuit) to the RDL 130.

Referring to FIG. 1 and FIG. 2A, in some arrangements, the RDL 130 is over the circuit 420 (or the control logic circuit) and electrically connected to one or more of the memory stacks 30A and 30B. In some arrangements, the electronic components 20A and 20B and the circuit 420 (or the control logic circuit) are at opposite sides of the RDL 130. In some arrangements, the memory stacks 30A and 30B and the circuit 420 (or the control logic circuit) are at opposite sides of the RDL 130. In some arrangements, the memory dies 310, 320, 33, and 340 are electrically connected to the circuit 420 (or the control logic circuit) through the RDL 130.

Referring to FIG. 1 and FIG. 2A, in some arrangements, the circuit 420 (or the control logic circuit) is configured to access data in one or more of the memory stacks 30A and 30B by a path (e.g., at least one of paths P2A, P2B, P2A′, and P2B′) passing the RDL 130. In some arrangements, the RDL 130 is between the electronic components 20A and 20B and the interconnector 40, and at least one of the electronic components 20A and 20B is configured to transmit an electrical signal to the circuit 420 (or the control logic circuit) of the circuit layer 40R of the interconnector 40 by an electrical path (e.g., at least one of the paths P2A, P2B, P2A′, and P2B′) passing the RDL 130 once.

Referring to FIG. 1 and FIG. 2A, in some arrangements, the electronic component 60 (or the passive component) is disposed adjacent to the circuit 420 (or the control logic circuit) and encapsulated by the encapsulant 120.

FIG. 2B is a top view of a package structure 1b in accordance with some arrangements of the present disclosure. In some arrangements, FIG. 1 shows a cross-section along a line 1-1′ in FIG. 2B. The structure illustrated in FIG. 2B is similar to that in FIG. 2A, and the differences therebetween are described as follows.

In some arrangements, the circuit 410 is exposed by the gap G2 between the memory stacks 30A and 30B from a top view perspective.

FIG. 2C is a top view of a package structure 1c in accordance with some arrangements of the present disclosure. In some arrangements, FIG. 1 shows a cross-section along a line 1-1′ in FIG. 2C. The structure illustrated in FIG. 2C is similar to that in FIG. 2A, and the differences therebetween are described as follows.

In some arrangements, the portion 420A and the portion 420B of the circuit 420 (or the control logic circuit) are located at opposite sides of the circuit 410 from a top view perspective.

FIG. 2D is a top view of a package structure 1d in accordance with some arrangements of the present disclosure. In some arrangements, FIG. 1 shows a cross-section along a line 1-1′ in FIG. 2D. The structure illustrated in FIG. 2D is similar to that in FIG. 2B, and the differences therebetween are described as follows.

In some arrangements, the circuit 410 is exposed by the gap G2 between the memory stacks 30A and 30B from a top view perspective.

FIG. 2E is a top view of a package structure 1e in accordance with some arrangements of the present disclosure. In some arrangements, FIG. 1 shows a cross-section along a line 1-1′ in FIG. 2E. The structure illustrated in FIG. 2E is similar to that in FIG. 2A, and the differences therebetween are described as follows.

In some arrangements, the package structure 1e includes a plurality of the structures (e.g., the package structures 1) illustrated in FIG. 2A. The package structures 1 are arranged in an array over a substrate 100A to form the package structure 1e. According to some arrangements of the present disclosure, multiple package structures 1 including the interconnectors 40 each with multiple functions can serve as combo dies integrated into the package structure 1e, such that the scalability and applications of the package structure 1e can be increased.

FIG. 3A is a cross-section of a package structure 3A in accordance with some arrangements of the present disclosure. The package structure 3A is similar to the package structure 1 in FIG. 1, and the differences therebetween are described as follows.

In some arrangements, the protective element 30u at least partially encapsulates the memory stack 30A and is spaced apart from the circuit layer 40R of the interconnector 40. In some arrangements, referring to FIG. 2A and FIG. 3A, the protective element 30u at least partially encapsulates the memory stack 30A and is spaced apart from the circuit 420 (or the control logic circuit). The protective element 30u may include an encapsulant, an epoxy resin having fillers, a molding compound (e.g., an epoxy molding compound or other molding compound), polyimide (PI), a phenolic compound or material, a material with a silicone dispersed therein, or a combination thereof.

In some arrangements, a top surface of the memory stack 30A is below top surfaces of the electronic components 20A and 20B with respect to the substrate structure 10. In some arrangements, the protective element 73 encapsulates the top surface of the memory stack 30A.

FIG. 3B is a cross-section of a package structure 3B in accordance with some arrangements of the present disclosure. The package structure 3B is similar to the package structure 1 in FIG. 1, and the differences therebetween are described as follows.

In some arrangements, the interconnector 40 is electrically connected to the RDL 110 through the conductive pads 110a. In some arrangements, the electronic components 60 are electrically connected to the RDL 110 through the conductive pads 60a. The electronic components 60 and the interconnector 40 are connected to the RDL 110 through Cu-to-Cu bonding.

FIG. 3C is a cross-section of a package structure 3C in accordance with some arrangements of the present disclosure. The package structure 3C is similar to the package structure 1 in FIG. 1, and the differences therebetween are described as follows.

The package structure 3C may include a substrate structure 10, electronic components 20A, 20B and 60, a memory stack 30A, a bridge component 40B, a logic die 50, connection elements 71 and 72, protective elements 73 and 74, and electrical contacts 80.

In some arrangements, the bridge component 40B includes a base layer 40s, a conductive layer 40c (also referred to as “a bridging circuit”) over the base layer 40s, conductive pads 40a on a surface 401 (also referred to as “a top surface”), conductive pads 40b on a surface 402 (also referred to as “a bottom surface”) opposite to the surface 401, and conductive vias 40V extending between the surfaces 401 and 402 to electrically connect the conductive pads 40a and 40b. The conductive layer 40c is configured to provide an electrical communication between the electronic components 20A and 20B. The conductive layer 40c is configured to provide an electrical communication between the memory stack 30A and at least one of the electronic components 20A and 20B.

In some arrangements, the electronic component 20A is configured to electrically communicate with the electronic component 20B by a path P1C passing the bridge component 40B. In some arrangements, the bridge component 40B is electrically connected to the electronic components 20A and 20B through portions of the RDL 130. In some arrangements, the path P1C passes a portion of the RDL 130 under the electronic component 20A, the conductive layer 40c of the bridge component 40B, and then a portion of the RDL 130 under the electronic component 20B. The path P1C passes only a few of heterogeneous interfaces, for example, interfaces between the RDL 130 and the bridge component 40B. As such, the path P1C may be relatively short compared to the path P1D which will be illustrated in FIG. 3D. Therefore, the power consumption may be lowered, and the signal delay and the latency may be relatively low.

The logic die 50 may be stacked with the memory stack 30A. In some arrangements, the logic die 50 is configured to access the memory stack 30A. In some arrangements, the logic die 50 is configured to access at least one of the memory dies 310, 320, 330, and 340. The logic die 50 may be configured to control access to the memory stack 30A. In some arrangements, the logic die 50 is configured to generate control signals to perform a write operation and/or a read operation. In some arrangements, the electronic component 20A is configured to access the memory stack 30A by sending a command signal to the logic die 50 which is configured to generate a control signal in response to the command signal to access the memory stack 30A. In some arrangements, the electronic component 20B is configured to access the memory stack 30A by sending a command signal to the logic die 50 which is configured to generate a control signal in response to the command signal to access the memory stack 30A. In some arrangements, the logic die 50 is disposed between the RDL 130 and the memory stack 30A. In some arrangements, the logic die 50 is disposed over the RDL 130 and electrically connected to the memory stack 30A through conductive pads 50b and connection elements 30c. In some arrangements, the logic die 50 is electrically connected to the RDL 130 through conductive pads 50a, connection elements 72, and conductive pads 130a. In some arrangements, the logic die 50 is spaced apart from the encapsulant 120. In some arrangements, the memory stack 30A has a width W30, and the logic die 50 has a width W50 substantially the same as the width W30 of the memory stack 30A. In some arrangements, the logic die 50 and the memory stack 30A are spaced apart from the electronic component 20A by a distance D1A. In some arrangements, the logic die 50 and the memory stack 30A are spaced apart from the electronic component 20B by a distance D1B. In some arrangements, the electronic components 20A and 20B are separated by a gap having a width W1 less than the width W1′ illustrated in FIG. 3D.

In some arrangements, the logic die 50 is configured to access data in the memory stack 30A by a path (e.g., at least one of paths P2C and P2C′) passing the RDL 130. In some arrangements, the path P2D passes a portion of the RDL 130 under the electronic component 20A, a portion of the conductive layer 40c, a portion of the RDL 130 under the logic die 50, and a portion of the logic die 50 where control signals are generated and transmitted to the memory stack 30A. In some arrangements, the path P2C′ passes a portion of the RDL 130 under the electronic component 20B, a portion of the conductive layer 40c, a portion of the RDL 130 under the logic die 50, and a portion of the logic die 50 where control signals are generated and transmitted to the memory stack 30A. With the width W50 of the logic die 50 being substantially the same as the width W30 of the memory stack 30A, the paths P2C and P2C′ may be relatively short compared to the paths P2C and P2C′ which will be illustrated in FIG. 3D, thus the computing speed may be increased, the power consumption may be reduced, and the signal decay and latency may be relatively low.

FIG. 3D is a cross-section of a package structure 3D in accordance with some arrangements of the present disclosure. The package structure 3D is similar to the package structure 3C in FIG. 3C, and the differences therebetween are described as follows.

In some arrangements, the package structure 3D includes two bridge components 40B. In some arrangements, the memory stack 30A has a width W30, and the logic die 50 has a width W50 greater than the width W30 of the memory stack 30A. In some arrangements, the memory stack 30A is spaced apart from the electronic component 20A by a distance D2A greater than the distance D1A illustrated in FIG. 1 and FIG. 3C, and the memory stack 30A is spaced apart from the electronic component 20B by a distance D2B greater than the distance D1B illustrated in FIG. 1 and FIG. 3C. In some arrangements, the electronic components 20A and 20B are separated by a gap having a width W1′ greater than the width W1 illustrated in FIG. 1 and FIG. 3C.

In some arrangements, the electronic component 20A is configured to electrically communicate with the electronic component 20B by a path P1D. The path P1D passes a plurality of heterogeneous interfaces, for example, interfaces between the RDL 130 and the bridge components 40B multiple times. As such, the path P1D may be relatively long compared to the path P1 illustrated in FIG. 1 and FIGS. 2A to 2D and the path P1C illustrated in FIG. 3C, thus the power consumption may be increased, the signal decay and latency may be relatively high.

In some arrangements, the logic die 50 is configured to access data in the memory stack 30A by a path (e.g., at least one of paths P2D and P2D′) passing the RDL 130 twice. In some arrangements, the path P2D passes a portion of the RDL 130 under the electronic component 20A, a portion of the conductive layer 40c, a portion of the RDL 130 under the logic die 50, and a portion of the logic die 50 where control signals are generated and transmitted to the memory stack 30A. In some arrangements, the path P2D′ passes a portion of the RDL 130 under the electronic component 20B, a portion of the conductive layer 40c, a portion of the RDL 130 under the logic die 50, and a portion of the logic die 50 where control signals are generated and transmitted to the memory stack 30A. As such, the paths P2D and P2D′ may be relatively long compared to the paths P2A and P2B illustrated in FIG. 1 and FIGS. 2A to 2D, thus the computing speed may be lowered, the power consumption may be increased, and the signal decay and latency may be relatively high.

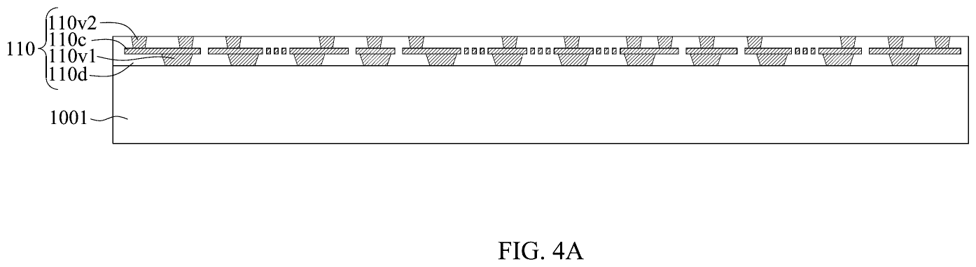

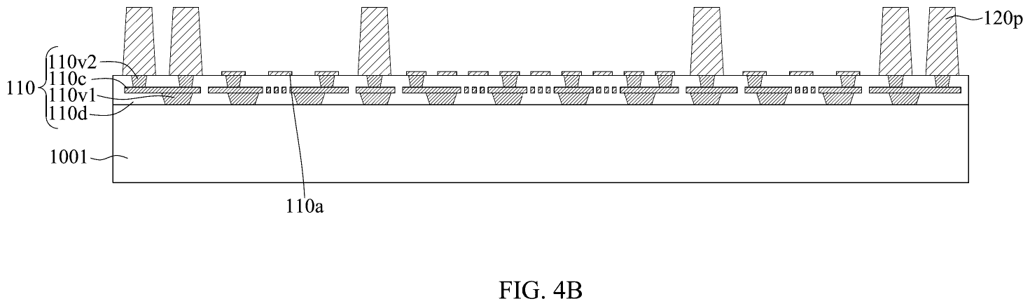

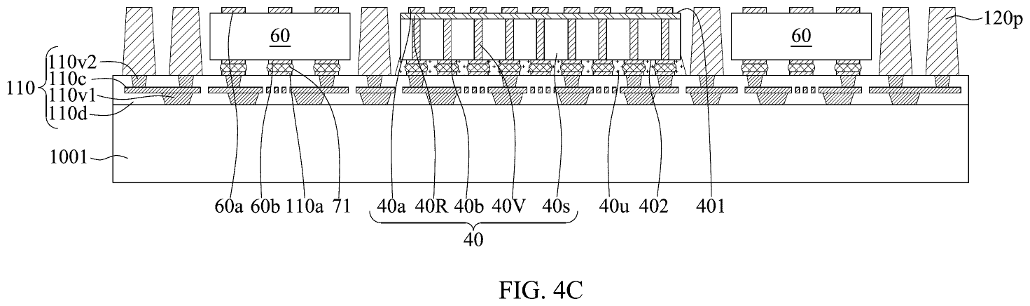

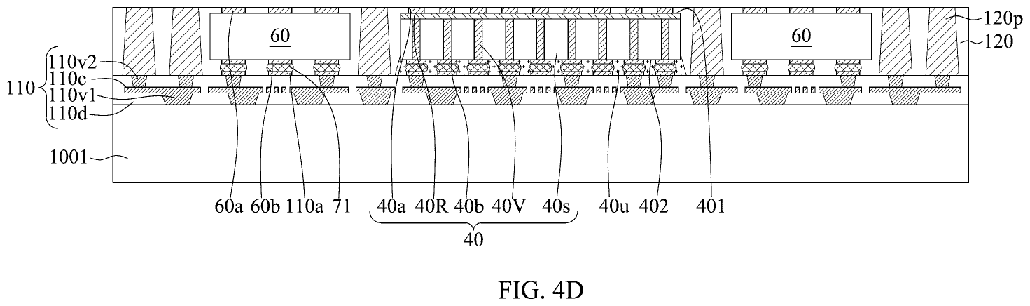

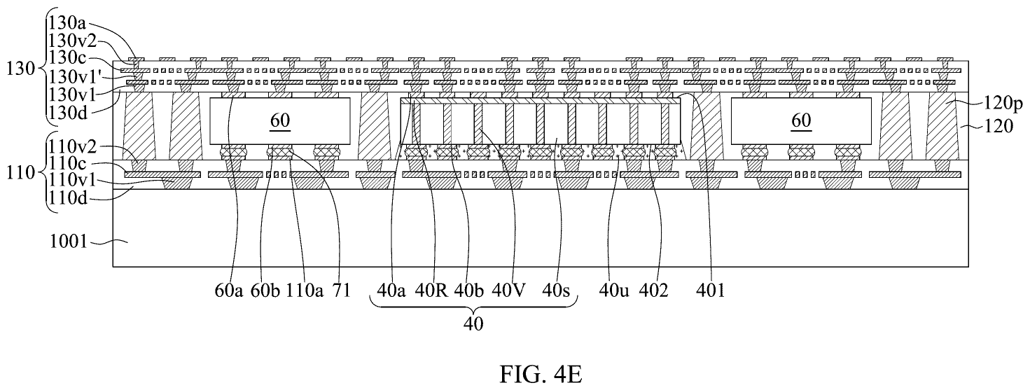

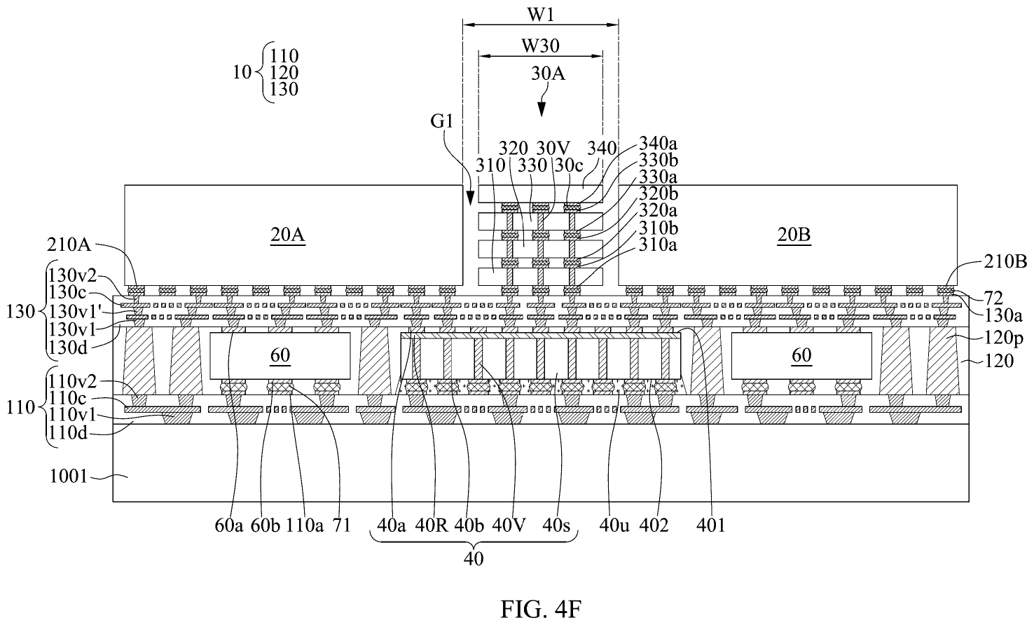

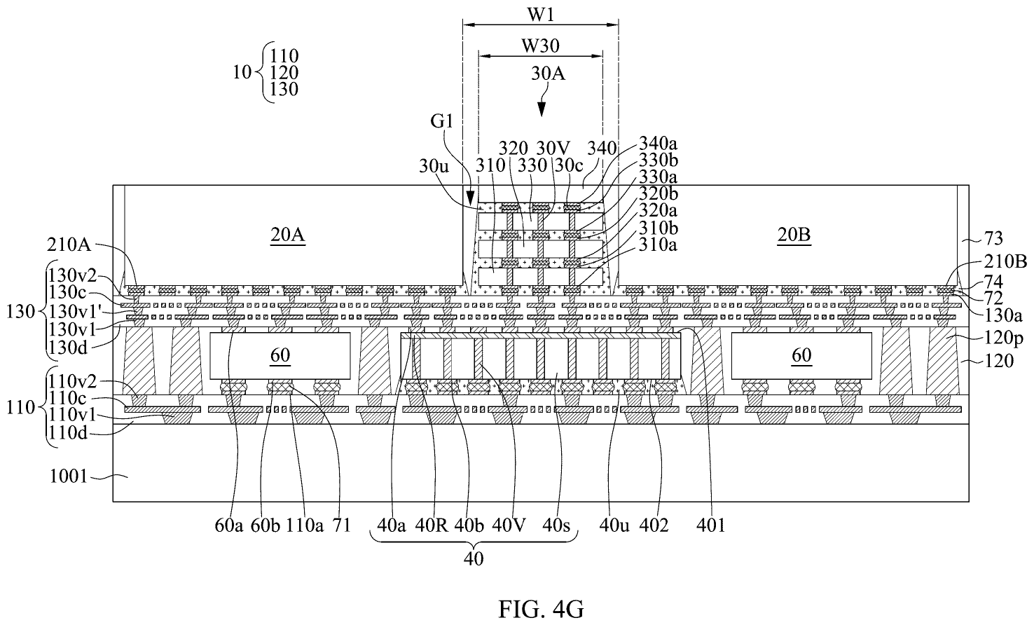

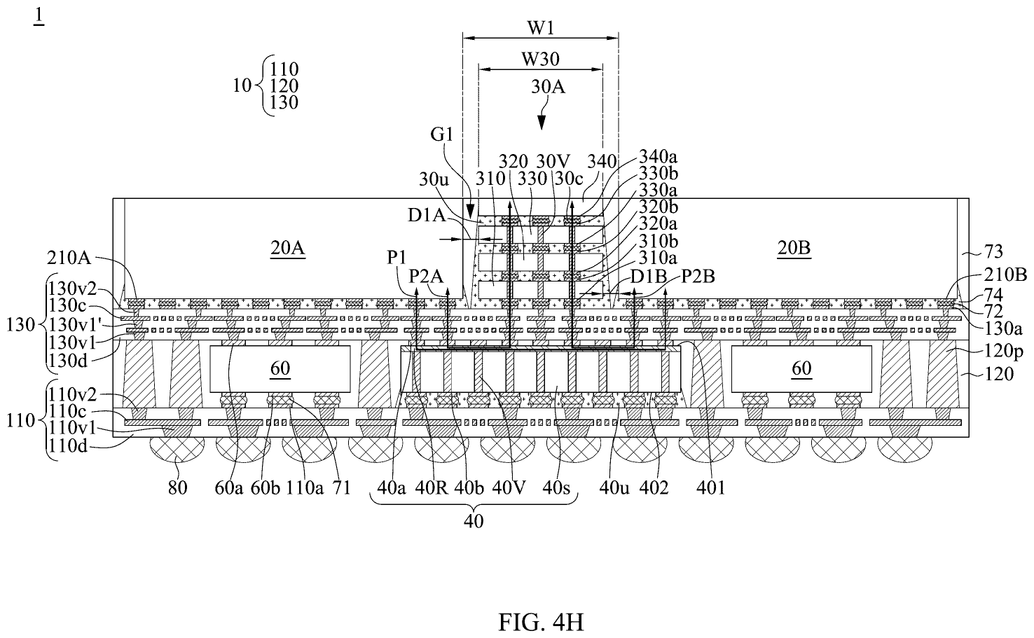

FIG. 4A to FIG. 4H illustrate various stages of an exemplary method of forming a package structure 1 in accordance with some arrangements of the present disclosure.

Referring to FIG. 4A, a carrier 1001 may be provided, and a RDL 110 may be formed on the carrier 1001. In some arrangements, the RDL 110 includes a dielectric layer 110d, at least one conductive layer 110c, and conductive vias 110v1 and 110v2.

Referring to FIG. 4B, conductive pillars 120p and conductive pads 110a may be formed on the RDL 110. The conductive pads 110a may be or include UBM layers.

Referring to FIG. 4C, an interconnector 40 and electronic components 60 may be connected to the RDL 110. In some arrangements, the interconnector 40 includes a base layer 40s, a circuit layer 40R, conductive pads 40a and 40b, and conductive vias 40V. In some arrangements, the interconnector 40 and the electronic components 60 are connected or bonded to the RDL 110 through conductive pads 40a and 60a, connection elements 71, and the conductive pads 110a. The bonding operation may be or include a solder-joint technique.

Referring to FIG. 4D, an encapsulant 120 may be formed to encapsulate the interconnector 40, the conductive pillars 120p, and the electronic components 60. In some arrangements, a molding compound or an encapsulating material may be disposed to cover the interconnector 40, the conductive pillars 120p, and the electronic components 60, and then a planarization operation (e.g., a grinding operation or a CMP operation) may be performed to remove portions of the interconnector 40, the conductive pillars 120p, and the electronic components 60 to form the encapsulant 120.

Referring to FIG. 4E, a RDL 130 may be formed on and electrically connected to the interconnector 40, the conductive pillars 120p, and the electronic components 60. In some arrangements, the RDL 130 includes conductive pads 130a, a dielectric layer 130d, at least one conductive layer 130c, and conductive vias 130v1 and 130v2.

Referring to FIG. 4F, electronic components 20A and 20B and a memory stack 30Amay be disposed on and electrically connected to the RDL 130. The electronic components 20A and 20B are connected or bonded to the RDL 130 through conductive pads 210A and 210B, connection elements 72, and conductive pads 130a. The bonding operation may be or include a solder-joint technique.

Referring to FIG. 4G, a protective element 73 may be formed to encapsulate the electronic components 20A and 20B and the memory stack 30A. In some arrangements, a molding compound or an encapsulating material may be disposed to cover the electronic components 20A and 20B and the memory stack 30A, and then a planarization operation (e.g., a grinding operation or a CMP operation) may be performed to remove portions of the electronic components 20A and 20B and the memory stack 30A to form the protective element 73.

Referring to FIG. 4H, the carrier 1001 may be removed, and electrical contacts may be formed on the bottom surface of the RDL 110. As such, the package structure 1 may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first electronic component and a second electronic component;
a data access structure disposed partially in a gap between the first electronic component and the second electronic component, wherein the data access structure comprises a logic portion and a storage portion, one of the logic portion and the storage portion is in the gap, and the other one of the logic portion and the storage portion is outside of the gap.

2. The package structure as claimed in claim 1, wherein one of the logic portion and the storage portion has a first size, the other one of the logic portion and the storage portion (30A) has a second size greater than the first size, the one having the second size is outside of the gap, and the one having the first size is in the gap.

3. The package structure as claimed in claim 2, wherein the storage portion is in the gap, and the logic portion is outside of the gap.

4. The package structure as claimed in claim 3, further comprising an interconnector configured to provide an electrical communication between the first electronic component and the second electronic component, wherein the logic portion is integrated into the interconnector.

5. The package structure as claimed in claim 4, wherein the interconnector further comprises a bridge portion distinct from the logic portion, the bridging portion is configured to provide the electrical communication between the first electronic component and the second electronic component, and one of the first electronic component and the second electronic component is configured to access the storage portion through the logic portion.

6. The package structure as claimed in claim 5, wherein the logic portion comprises a first part and a second part, the first electronic component is configured to access the storage portion by sending a first command signal to the first part which is configured to generate a first control signal in response to the first command signal to access the storage portion, and the second electronic component is configured to access the storage portion by sending a second command signal to the second part which is configured to generate a second control signal in response to the second command signal to access the storage portion.

7. The package structure as claimed in claim 6, wherein the first part and the second part of the logic portion are located at opposite sides of the bridge portion from a top view perspective.

8. The package structure as claimed in claim 1, wherein a width of the logic portion is greater than a width of the gap between the first electronic component and the second electronic component.

9. The package structure as claimed in claim 5, wherein the storage portion comprises a first memory stack and a second memory stack over the interconnector, and the bridge portion is at least partially between the first memory stack and the second memory stack from a top view perspective.

10. The package structure as claimed in claim 4, wherein the interconnector is configured to provide the electrical communication between the first electronic component and the second electronic component along a first path, and at least one of the first electronic component and the second electronic component is configured to access the storage portion along a second path substantially parallel to the first path.

11. The package structure as claimed in claim 10, wherein the first path vertically overlaps the storage portion rom a cross-sectional view perspective.

12. A package structure, comprising:
a first electronic component and a second electronic component;
a memory stack comprising a plurality of memory dies stacked over each other; and
a bridging component comprising a first portion configured to provide an electrical communication between the first electronic component and the second electronic component and a second portion configured to control access to the memory stack, wherein the second portion of the bridging component and the memory stack collectively construct a memory structure.

13. The package structure as claimed in claim 12, further comprising a redistribution layer (RDL), wherein the memory stack comprises a stack of DRAMs, and the memory stack and the second portion of the bridging component are at opposite sides of the RDL.

14. The package structure as claimed in claim 13, wherein the second portion of the bridging component is configured to access data in the memory stack by a path passing the RDL.

15. The package structure as claimed in claim 14, further comprising a passive component disposed adjacent to the second portion of the bridging component and encapsulated by the encapsulant, wherein the second portion of the bridging component overlaps a portion of the memory stack, a portion of the first electronic component, and a portion of the second electronic component from a top view perspective.

16. The package structure as claimed in claim 12, further comprising:
a first RDL between the memory stack and the bridging component, wherein the first RDL electrically connects a top surface of the bridging component to the memory stack; and
a second RDL below the bridging component and electrically connected to a bottom surface opposite to the top surface of the bridging component.

17. A package structure, comprising:
a first electronic component and a second electronic component separated from each other by a gap; and
a third electronic component comprising a first portion disposed in the gap and a second portion extending outwards from the gap, wherein a size of the second portion is greater than a size of the first portion.

18. The package structure as claimed in claim 17, wherein the first portion is dissembled from the second portion, and the first portion is electrically connected to the second portion through a conductive structure.

19. The package structure as claimed in claim 17, wherein the first portion of the third electronic component is configured to be unable to operably communicate with the first electronic component or the second electronic component without operating in conjunction with the second portion.

20. The package structure as claimed in claim 19, wherein the second portion of the third electronic component is configured to operate in conjunction with the first portion to operably communicate with the first electronic component or the second electronic component.
